(19) United States
(12) Patent Application Publication
(10) Pub. No.: US 2008/0079051 A1
(43) Pub. Date: Apr. 3, 2008

(54) Varactor with halo implant regions of opposite polarity

(76) Inventors: Luo Yuan, Sunnyvale, CA (US); Derchang Kau, Cupertino, CA (US); Wei-Kai Shih, Beaverton, OR (US); Shafqat Ahmed, San Jose, CA (US); Brian K. Armstrong, Colorado Springs, CO (US)

Correspondence Address: TROP PRUNER & HU, PC, 1616 S. VOSS ROAD, SUITE 750, HOUSTON, TX, 77057-2631, US

(21) Appl. No.: 11/529,943

(22) Filed: Sep. 29, 2006

(51) Int. Cl. H01L 29/94; H01L 21/20

(52) U.S. Cl. 257/312; 438/379; 257/E29.345

(57) ABSTRACT

A metal oxide semiconductor varactor may be formed with HALO implants regions having an opposite polarity from the polarity of the well of the varactor. The HALO implant regions can be angled away from the source and drain. The HALO implant regions can stop the depletion from continuing as the bias voltage applied to the gate continues to increase. Stopping that depletion can create a constant capacitance when the varactor is in a depletion bias.

### BACKGROUND

This relates generally to integrated circuits and particularly to a variable capacitor using a complementary metal-oxide semiconductor (CMOS) process.

Varactors can be used in capacitance tuning and device matching for integrated circuits. A varactor's gate capacitance changes based on the gate and voltage applied to the varactor. Changing the voltage applied to the gate of a varactor can be used to tune a circuit.

In a varactor created using metal-oxide semiconductor technology, a variable depletion capacitance can be created. The variable depletion capacitance in addition to the gate oxide capacitance, the overlapped capacitance and the fringing capacitance can increase or decrease the tuning range of the varactor. These capacitances are formed between areas of a semiconductor substrate that are doped at different polarities and different concentrations.

### BRIEF DESCRIPTION OF THE DRAWINGS

FIG. 1 depicts a cross-sectional view of an embodiment of a semiconductor varactor.

FIG. 2 depicts a cross-sectional view of an embodiment of a semiconductor varactor.

FIG. 3 depicts a cross-sectional view of the capacitance characteristics of an embodiment of a semiconductor varactor.

FIG. 4 is a flowchart of an embodiment of a method of manufacturing a varactor.

FIG. 5 depicts one embodiment of a voltage-controlled oscillator including a varactor.

FIG. 6 depicts one embodiment of a system incorporating a voltage-controlled oscillator including a varactor.

### DETAILED DESCRIPTION

In a digital varactor, one of two distinct capacitance levels can be created depending on the voltage applied to the gate of the varactor. As the voltage applied to the gate of the varactor reaches a threshold, the capacitance can change from a first level to a second level. In one embodiment, two distinct capacitance levels can be created by implant regions having an opposite polarity from the polarity of the well of the varactor. The voltage range for a transition to occur from a first capacitance to a second capacitance can be reduced, by implanting the well of the varactor at a lower concentration than transistor well implants of the same polarity in the semiconductor process.

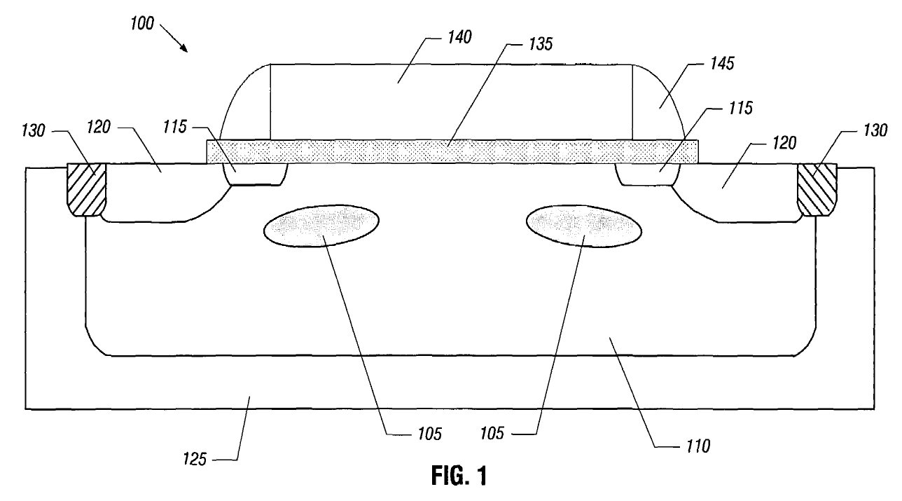

Referring to the figures, FIG. 1 depicts a cross-sectional view of an embodiment of a semiconductor varactor. A complementary metal-oxide semiconductor (CMOS) varactor 100 may be formed in a semiconductor substrate 125. In one embodiment, the substrate 125 may be a lightly doped P-type silicon. The substrate 125 can have a well 110 created by a lightly doped N-type region, in one embodiment. The lightly doped regions underneath the gate electrode 140 enable a transition from the accumulation to depletion to occur in a smaller voltage range, in one embodiment. As the depletion region becomes larger due to an increase in gate bias voltage, the channel capacitance becomes smaller.

Formed over the well 110 can be a gate oxide 135 and a gate electrode 140. In one embodiment, the gate electrode 140 is heavily doped N-type polycrystalline silicon. Sidewall spacers 145 on the sides of the gate electrode 140 can define the positioning for the source and the drain regions 120.

HALO implant regions 105 can create a buried region of opposite doping polarity underneath the surface channel to act as a depletion stopping layer, slowing down the growth of the depletion region when the gate bias becomes more negative.

Forming the HALO implanted regions 105 using an opposite polarity from the well 110, can cause the depletion capacitance to remain at a relative constant value. An accumulation capacitance can be at a relatively constant value creating two distinct capacitance states, one in accumulation and one in depletion.

The HALO implant regions 105 can be buried below the surface of the well 110 so that they are not in contact with the gate oxide 135. HALO implant regions 105 can be heavily doped P-type relative to the lightly doped well 110. A trench oxide 130 can define the position of the well 110 and define the limits of the source and the drain regions 120 in the well. The source and drain regions 120 can be heavily doped N-type relative to the lightly doped well 110. Adjacent to the source and the drain regions 120 can be a lightly doped drain (LDD) implants 115, in one embodiment. The LDD implants can be doped N-type. In one embodiment, the concentration of the LDD implants is between that of the heavily doped source and drain regions 120 and the lightly doped well 110.

The HALO implant regions can be at an angle, in one embodiment. The angle of the implant, in one embodiment, can be approximately 40 degrees relative to the gate oxide 135, but can also be higher or lower than 40 degrees in other embodiments. Angling the HALO implant region can result in the HALO implant regions being closer to the gate oxide 135 and further from the source and the drain regions 120.

A first capacitance state occurs when the gate voltage is more positive than the source or drain voltage, also called accumulation bias. The second capacitance state occurs when the gate voltage is more negative than the source or drain voltage, also called depletion bias. Reducing the doping concentration of the well can reduce the voltage transition range between the two distinct capacitance states, in one embodiment.

An embodiment of the varactor can be formed with a complementary metal oxide semiconductor process. The complementary metal oxide semiconductor process can allow the polarities of the different regions of the varactor to be reversed, for example the N-type regions can become P-type regions and the P-type regions can become N-type regions. Reversing the polarity causes the high capacitance state to occur when the gate voltage is more negative than the source and the drain, known as accumulation bias. The low capacitance state occurs then the gate voltage is more positive than the source and the drain voltages, known as depletion bias.

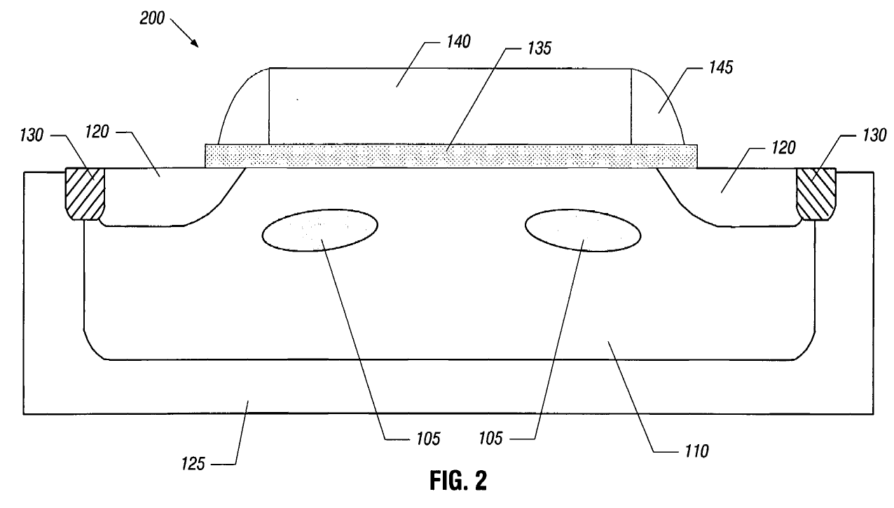

FIG. 2 depicts a cross-sectional view of an embodiment of a semiconductor varactor 200. The LDDs 115 in FIG. 1 at the same polarity as the well 110 may be removed, in one embodiment. The LDD implants in FIG. 1 can create additional capacitance between the gate electrode 140 and the well 110. Removing the LDD implants can increase the tuning range in one embodiment and further reduce the voltage range in which the capacitance is in transition from the first state to the second state.

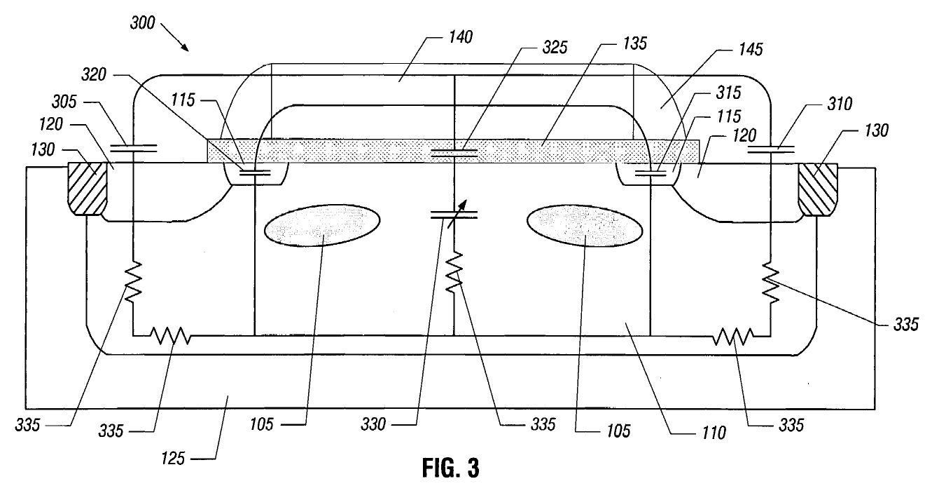

FIG. 3 depicts an equivalent circuit 300 for the characteristics of the varactor 100 shown in FIG. 1. Capacitance is created by overlapping layers of different polarities or doping concentrations. The equivalent circuit 300 can include the fringing capacitances 305 and 310 created between the gate electrode 140 and the source and drain regions 120. The fringing capacitances 305 and 310 are created when two different layers overlap. The fringing capacitances 305 and 310 are between the side surfaces of the gate electrode 140 and the surface of the source and drain regions 120.

An oxide capacitance 325 can be created between a gate electrode 140 and the well 110. Connected to the oxide capacitance 325 can be the variable depletion capacitance 330. The variable depletion capacitance 330 can change according to the width of the channel depletion region. As the width of the channel depletion region changes due to the voltage applied to the gate electrode the variable depletion capacitance changes. Overlap capacitances 315 and 320 can be created between the gate electrode 140 and the well 110 in the LDD regions 115. The overlap capacitances 315 and 320 are created by the overlapping of the gate oxide 135 and the source and drain regions 120. The well resistance 335 can describe the resistive path from the border of the depletion region to the source and drain region.

Improving the tuning range and transition abruptness of the varactor 100, can be accomplished by removing the overlap capacitance 315 and 320 from the circuit 300. To remove the overlap capacitance 315 and 320 the LDD implant region can be removed. Removing the implant region can be accomplished by applying a mask and applying lithography. A circuit 300 without the overlap capacitances 315 and 320 in parallel with the variable depletion capacitance 330 can improve the tuning range in one embodiment.

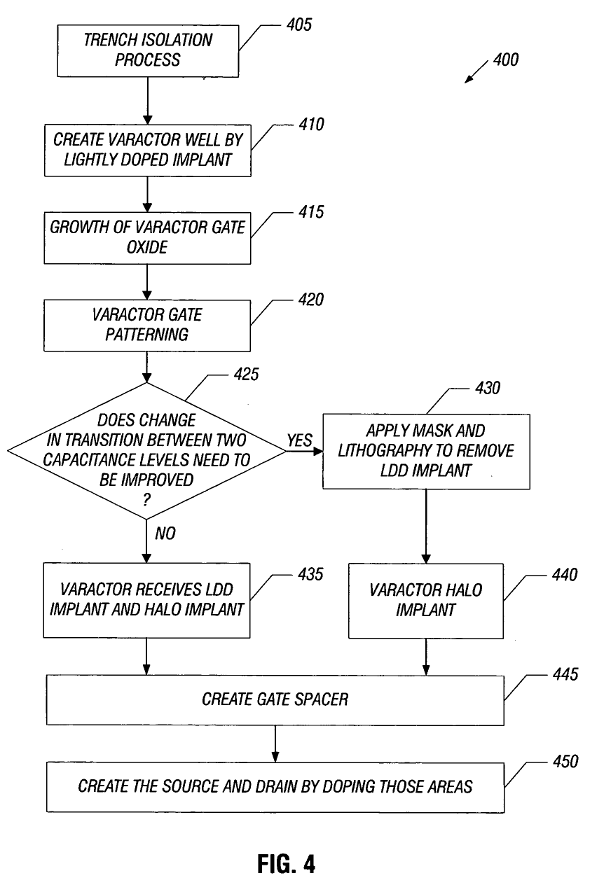

FIG. 4 is a flowchart of an embodiment of a method of manufacturing a varactor. The method for manufacturing 400 the varactor can begin at block 405 where a trench isolation process occurs to form the trench oxide 130. The varactor well can be created at block 410 by a lightly doped implant of impurities to change the characteristics of the substrate. The characteristics may include the polarity. A gate oxide can be grown at block 415 over the varactor well. The varactor gate can be formed at block 420.

A determination can be made to whether the voltage range between the two capacitance levels of the varactor is adequate at diamond 425. If the voltage range between the two distinct capacitance levels needs to be reduced at diamond 425, two masks can be used, in one embodiment, one for the LDD and one for the halo. A mask and lithography can be applied to block the LDD implant from the varactor at block 430. The LDD implant regions may still be used in a conventional transistor on the semiconductor substrate. If the mask and lithography are applied at block 430 to block the implantation of the LDD, a HALO implant region can be formed in the varactor at block 440.

If the decision is that the voltage range is adequate at diamond 425, at block 435 the LDD implant and HALO implant region can be formed in, one embodiment of a varactor, with one mask process.

At block 445 the gate spacer can be created. In some embodiments, the varactor is formed adjacent to transistors on the substrate using a complementary metal oxide semiconductor process. The gate spacers can be created at the same time as the transistor spacers are formed.

The source and drain implants are undertaken to form the source and drain regions 120 and to highly dope the gate electrode 140 at block 450.

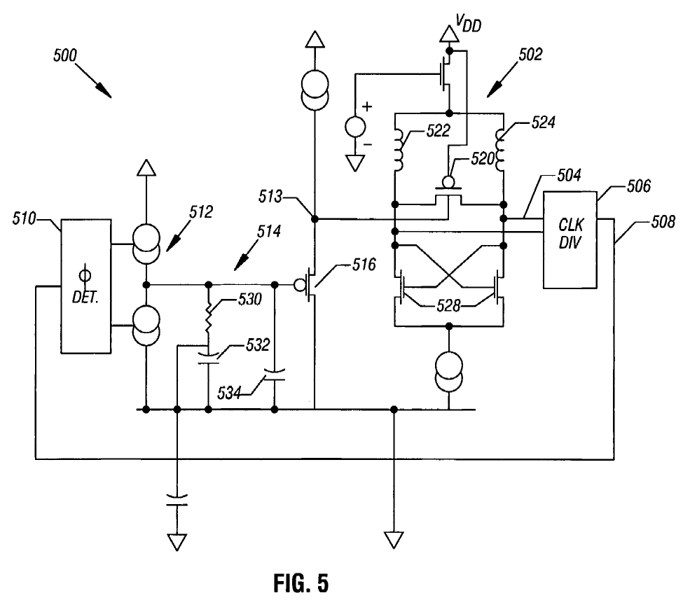

FIG. 5 depicts one embodiment of a phase locked loop 500. Other current implementations are also contemplated. The phase locked loop 500 can include a voltage controlled oscillator core 502, which outputs clock pulses 504 to an optional clock divider 506. In some embodiments a clock divider may divide the clock pulses 504 to lower frequency clock pulses 508, which are input to a phase detector 510. In one embodiment, the division ratio may be one and the phase locked loop 500 has no clock divider. The phase detector 510 can drive a charge pump 512, which drives a loop filter 514. The loop filter 514 can drive the buffer 516, which drives the voltage controlled oscillator core 502 to output the clock pulses 504.

The voltage controlled oscillator core 502 can include a complementary metal oxide semiconductor varactor 520, whose gate electrode 140 is coupled to the voltage VDD and whose substrate 125 is coupled to the controlled voltage 513 as supplied by the phase detector 510 through the buffer 516. The complementary metal oxide semiconductor varactor 520 can be a complementary metal oxide semiconductor varactor with HALO implant regions 105 having a polarity opposite from the polarity of the well 110.

The voltage controlled oscillator core 502 may also include a pair of inductors 522, 524, which may be formed in the substrate 125 with the complementary metal oxide semiconductor varactor 520. The voltage controlled oscillator core 520 can also include MOSFETs 528.

The loop filter 514 can include a resistor 530 and a pair of capacitors 532 and 534.

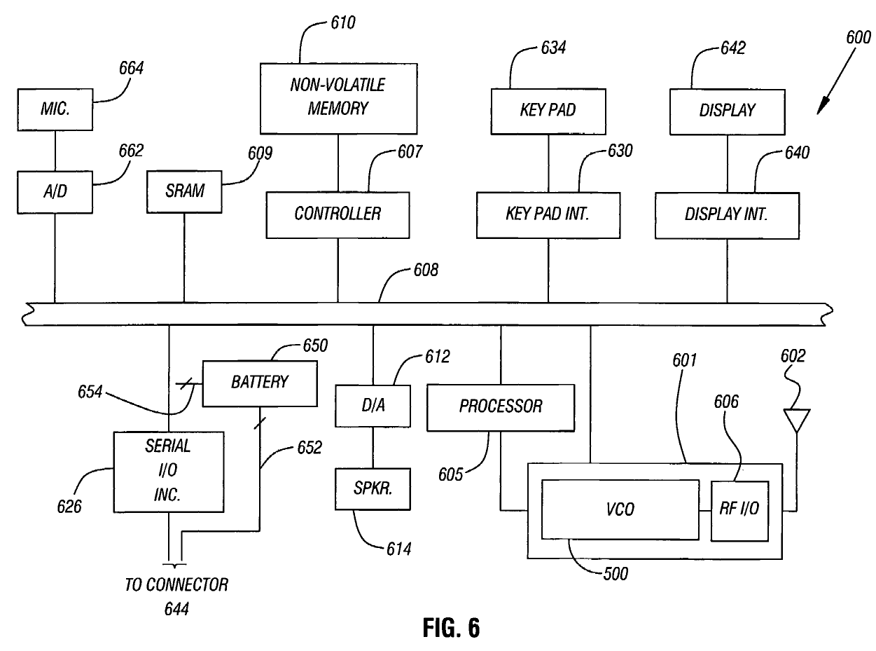

FIG. 6 depicts one embodiment of a system incorporating a varactor. The system may be for example a cellular telephone 600 but is not limited to a cellular phone 600. The cellular telephone 600 includes a communication unit 601 that serves as an interface of the cellular telephone 600 to a cellular antenna 602. The communication unit 601 can include a voltage-controlled oscillator 500 and a radio frequency input output device 606. The voltage-controlled oscillator 500 can include a varactor with HALO implant regions having an opposite polarity from the well of the varactor. The communication unit 601 can be a transmitter, receiver, or a transceiver. The communication unit 601 is coupled to a bus 608 of the cellular telephone 600 to communicate data with a memory 609, for example a static random access memory (SRAM) of the cellular telephone 600. A processor 605 can refer to a multi-core processor. The processor 605 can be coupled to the bus 608 to direct the communication of data between the memory 609 and the communication unit 601. In this manner, if incoming data is received, the processor 605 can transfer the data from the memory 609 to a digital-to-analog converter 612 to a speaker 614 to play audio. Similarly, the processor 605 directs captured voice data from a microphone 664 through an analog-to-digital (A/D) converter 662 to the memory 609.

The cellular telephone 600 can include an input/output (I/O) interface 626 that establishes electrical connection with the connector 644. In this manner, the I/O interface 626 may receive code from the connector 644, and the code can be sent from the processor 605 to the controller 607 to store on the non-volatile memory 610.

Among the other features of the cellular telephone 600, a key pad 634 may be used to enter telephone numbers and may be interfaced between the bus 608 via a keypad interface 630. Furthermore, the processor 605 may drive a display 642 through a display interface 640 that is coupled between the display 642 and the bus 608. The cellular telephone 600 also includes a battery 650 that is coupled to conductive traces, or lines 654, to supply power to the components of the cellular telephone and is coupled to conductive traces, or lines 652, that extend to and are accessible through the connector 644. The lines 652 may be used for purposes of charging the battery 650.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
forming a HALO implant region of a second polarity in a well of a first polarity in a semiconductor varactor.

2. The method of claim 1, including forming a lightly doped drain region.

3. The method of claim 2, including implanting the lightly doped drain region at the same polarity as the well.

4. The method of claim 1, including forming the semiconductor varactor without a lightly doped drain region.

5. The method of claim 4, including masking the lightly doped drain region to improve a capacitive tuning range of the semiconductor varactor.

6. The method of claim 1, including angling the HALO implant region of the second polarity in the well of the first polarity.

7. The method of claim 6, including implanting the HALO implant region closer to a gate oxide of the semiconductor varactor than to one of a source region and a drain region of the semiconductor varactor.

8. The method of claim 1, including burying the HALO implant region of the second polarity within the well of the first polarity.

9. The method of claim 1, including forming the HALO implant regions to create substantially constant capacitance in a depletion state of the semiconductor varactor.

10. The method of claim 1, including applying a complementary metal-oxide semiconductor process to form the semiconductor varactor.

11. The method of claim 1, including applying a voltage to the semiconductor varactor to tune a voltage controlled oscillator.

12. The method of claim 1, including doping the well at a lower concentration than the HALO implant regions.

13. A varactor comprising:
a substrate;
a first polarity well in the substrate; and
HALO implant regions of an opposite polarity in the first polarity well.

14. The varactor of claim 13, including a source and drain of the first polarity formed in the substrate.

15. The varactor of claim 14, including lightly doped drain implants of the first polarity adjacent to the source and drain.

16. The varactor of claim 14, wherein the varactor is free of lightly doped drain implants.

17. The varactor of claim 14, wherein at least one of the HALO implant regions is angled away from one of the source and the drain.

18. A voltage controlled oscillator comprising:
a varactor including a substrate with an opposite polarity HALO implant region in a first polarity well.

19. The oscillator of claim 18, including a source and drain of the first polarity formed in the substrate.

20. The oscillator of claim 19, including lightly doped drain implants of the first polarity adjacent to the source and drain.

21. The oscillator of claim 18, wherein the varactor is free of lightly doped drain implants.

22. A system comprising:
a processor;
a static random access memory coupled to the processor;
a voltage controlled oscillator on a substrate; and
a varactor including a first polarity well in the substrate and HALO implant regions of an opposite polarity in the first polarity well.

23. The system of claim 22, including a source and drain of the first polarity formed in the substrate.

24. The system of claim 23, including lightly doped drain implants of the first polarity adjacent to the source and drain in the varactor.

25. The system of claim 22, wherein the varactor is free of lightly doped drain implants.
